(19) United States
(12) Patent Application Publication
(10) Pub. No.: US 2008/0099193 A1
(43) Pub. Date: May 1, 2008

(54) SELF-REGULATED COOLING MECHANISM

(76) Inventors: Slavek Peter Aksamit, Durham, NC (US); James Gordon McLean, Fuquay-Varina, NC (US); Cristian Medina, Durham, NC (US)

Correspondence Address: IBM CORPORATION (SS/NC);c/o STREETS & STEELE, 13831 NORTHWEST FREEWAY, SUITE 355, HOUSTON, TX, 77040, US

(21) Appl. No.: 11/555,348

(22) Filed: Nov. 1, 2006

(51) Int. Cl. H05K 7/20; G05D 23/00

(52) U.S. Cl. 165/300; 165/80.3; 361/697

(57) ABSTRACT

Regulating the temperature of a heat-generating device within a desired range using shape memory materials disposed on a heat sink. According to one embodiment, cooling fins are placed upon a heat-generating device. Fluid flows through the cooling fins to remove heat from the device. A shape memory material is placed within the path of fluid flow to regulate the amount of fluid flow in response to stimuli at desired low and high operating temperatures of the heat-generating device. At the low desired device operating temperature, the shape memory material restricts the amount of fluid flow through the cooling fins. At the high desired device operating temperature, the shape memory material does not restrict fluid flow through the cooling fins.

### BACKGROUND OF THE INVENTION

1. Field of the Invention

The present invention relates to regulating the temperature of a heat-generating device.

2. Description of the Related Art

Devices of many types have an optimum operating temperature range. For this reason, a great deal of design and engineering emphasis has been placed upon cooling, to prevent shortened component lives due to exposures to temperatures above a threshold temperature. Typically, the greatest danger to a device is overheating of components, resulting in degradation of lifespan, performance, and efficiency. However, there may also be undesirable effects of operating below threshold temperatures, such as a loss in efficiency, or damage due to repeated thermal cycling. In addition, devices must be designed to tolerate a greater range of operating temperatures when only the upper end of an operating temperature range is controlled.

Many cooling configurations employ a system involving the usage of cooling fins that carry heat away from the device. Fluid flow is then forced between the fins to remove heat from the cooling fins. This process is referred to as forced convection. Cooling fins are effective because they are efficient conductors of thermal energy and have a high degree of surface area that facilitates heat exchange with the fluid. Often the amount of cooling that a device will experience is controlled by mechanically adjusting the fluid flow rate of a cooling fluid passed between the cooling fins, such as by varying fan speeds or the angle of flow.

Controlling the temperature range in which a device operates will result in less stringent design requirements and specifications for the device. A carefully controlled environment and relaxed design requirements may also reduce manufacturing costs, as well as increase predictability of performance, reliability, and efficiency. It would be desirable to have a method for adjusting the rate at which a heat sink having cooling fins would transfer heat away from a heat-generating device. It would also be desirable if the method could control the temperature of multiple heat-generating devices on a device by device basis. It would be even more desirable to have a method of regulating the temperature of multiple heat-generating devices within their own unique temperature ranges using a common cooling fluid stream.

### SUMMARY OF THE INVENTION

In one embodiment, the invention makes use of a shape memory material to regulate the temperature of a heat-generating device within a desired range. Cooling fins are disposed in thermal contact with a heat generating device. Heat is removed by fluid flowing between the cooling fins. The fluid may be air, liquid, or a combination of air and liquid. A shape memory material, which expands and contracts in response to a stimulus, is within the path the fluid flow. At a desired low operating temperature of the heat generating device, the shape memory material will expand in response to a stimulus to restrict fluid flow, and therefore reduce the amount of heat removed from the device. At a desired high operating temperature of the heat generating device, the shape memory material will contract in response to a stimulus to allow unrestricted fluid flow, and therefore not affect the amount of heat removed from the device. The stimulus may be the temperature of the heat-generating device, or a signal generated in response to the temperature of the heat-generating device. A plurality of shape memory materials may be utilized to achieve fine control of fluid flow, with each shape memory material responding to different stimuli, or different levels of stimuli.

In another embodiment, the invention makes use of shape memory materials to regulate the temperature of multiple heat-generating devices within ranges desirable to each heat-generating device. Cooling fins are disposed in thermal contact with the heat generating devices. Heat is removed by fluid flowing between the cooling fins. The fluid may be air, liquid, or a combination of air and liquid. Shape memory materials are selected to expand to restrict fluid flow at the desired low temperature and contract so as not to restrict floe at the desired high temperature of each heat-generating device. The shape memory material may expand and contract in response to each heat-generating device temperature, or a stimulus generated based upon the heat-generating device temperature. A plurality of shape memory materials may be utilized to achieve fine control of fluid flow, with each shape memory material responding to different stimuli, or different levels of stimuli.

The invention provides a method of regulating the temperature of a heat-generating device comprising. Conveying fluid through a passageway to cool a heat-generating device, regulating the amount of fluid conveyed through the passageway by utilizing a shape memory material, wherein the shape memory material expands to restrict fluid flow in response to a stimulus at a desired low device temperature, and contracts so as not to restrict flow in response to a stimulus at a desired high device temperature. A plurality of shape memory materials may be utilized to achieve fine control of fluid flow, with each shape memory material responding to different stimuli, or different levels of stimuli.

### BRIEF DESCRIPTION OF THE DRAWINGS

FIG. 1 is a side view of cooling fins disposed on a heat-generating device, with shape memory materials disposed in thermal contact with the fin, and a fan to circulate air through the cooling fins.

FIG. 2 is a side view of cooling fins disposed on a heat-generating device, with shape memory materials disposed in thermal contact with the fin, and alternate placement of fan(s) to circulate air through the cooling fins.

FIG. 3 is a plan view of cooling fins disposed on a heat-generating device, with shape memory materials disposed in thermal contact with the fin.

FIG. 4 is a plan view of cooling fins disposed on a heat-generating device, with shape memory materials disposed in thermal contact with the fin, while restricting fluid flow.

FIG. 5 is a plan view of cooling fins disposed on a heat-generating device, with an alternate disposition of shape memory materials in thermal contact with the fin.

FIG. 6 is a plan view of cooling fins disposed on a heat-generating device, with an alternate disposition of shape memory materials disposed in thermal contact with the fin, while restricting fluid flow.

FIG. 7 is a plan view of cooling fins disposed on a heat-generating device, with an alternate disposition of shape memory materials in thermal contact with the fin.

FIG. 8 is a plan view of a third alternative for disposing shape memory materials on the cooling fins.

FIG. 9 is a plan view of cooling fins disposed on a heat-generating device, with a plurality of shape memory materials disposed in thermal contact with the cooling fins.

FIG. 10 is a plan view of cooling fins disposed on a heat-generating device, with a plurality of shape memory materials disposed in thermal contact with the cooling fins.

FIG. 11 is a plan view of cooling fins disposed on a heat-generating device, with a plurality of shape memory materials disposed in thermal contact with the cooling fins.

FIG. 12 is a plan view of cooling fins disposed on a heat-generating device, with a shape memory material disposed in the path of fluid flow.

FIG. 13 is a plan view of cooling fins disposed on a heat-generating device, with a plurality of shape memory materials disposed in the path of fluid flow.

### DETAILED DESCRIPTION OF PREFERRED EMBODIMENTS

The present invention efficiently regulates temperature within a desired operating range by regulating fluid flow through the cooling fins of a heat sink disposed upon a heat-generating device. This is accomplished by utilizing shape memory materials to expand and contract within the path of fluid flow through the cooling fins. The amount of heat dissipated is directly related to the flow rate of fluid flow across cooling fins. When the temperature of the heat-generating device drops below the desired operating range, the shape memory material will expand to restrict fluid flow across cooling fins to lessen the amount of heat dissipated. Conversely, when the temperature of the heat-generating device elevates above the desired operating range, the shape memory material will contract to allow peak fluid flow across cooling fins to maximize the amount of heat dissipated. By adjusting the size of the opening available for fluid flow, the amount of heat dissipated from a heat-generating device is regulated.

Fluid typically flows through cooling fins in several ways. One method is to use a fan to push or blow air through the fins. Another method utilizes a fan to pull or draw air across the fine. Air might also be allowed to passively flow through the fins due to temperature variations in the environment of the cooling fin. When liquid cooling is utilized, a pump may be employed to force the fluid through, or draw the fluid through the cooling fins. Also, a gravity feed may be utilized to convey fluid through the cooling fins.

A shape memory material in the context of this specification is intended to encompass a shape memory polymer, a shape memory alloy, or any combination of the above materials. For example, one such shape memory polymer is copolymer of oligo(e-caprolactone)dimethacrylate and n-butyl acrylate, combined in varying amounts to form a cross-linked polymer network tailored for suitable mechanical strength and a suitable transition temperature. A suitable shape memory alloy is the nickel-titanium alloy known as Nitinol.

A shape memory alloy is a metal alloy that “remembers” its geometry. While “one-way” and “two-way” shape memory alloys exist, the any reference within this specification will refer to “two-way” shape memory alloys. A “two-way” shape memory alloy material remembers two different shapes. The shape memory alloy changes shape in response to external stimuli. For example, a “two-way” shape memory alloy that responds to changes in temperature would have two distinct shapes: one at low temperatures, and one at a higher temperature. In this manner, the desired configuration of the shape memory alloy can be determined by adjusting the ambient temperature.

A shape memory polymer is a polymer that “remembers” its geometry. Shape memory polymers have a defined shape and through stimuli this shape is easily transformed in a manner analogous to the shape memory alloy described above.

In a preferred embodiment, the shape memory material is disposed directly in contact with the cooling fin. The shape memory material is thereby placed at, or near the temperature of the device being protected. The shape memory material is selected to expand at the lowest desired operating temperature of the device to restrict fluid flow through the cooling fins. The shape memory material is also selected to contract at a higher, specified design temperature to allow peak fluid flow through the cooling fins. In this manner the shape memory material regulates the amount of heat dissipated from the device in response to the device's current temperature, thereby maintaining a desired range of operating temperature. By utilizing a shape memory material specifically coordinated to each device, many heat-generating devices can be regulated to differing temperatures utilizing a single cooling fluid stream.

In a second embodiment, two or more shape memory materials are disposed in thermal contact with the cooling fins, effectively realizing the same temperature as the heat-generating device being protected. The two or more shape memory materials are designed or selected to expand or contract at different temperatures. A first shape memory material may expand to partially restrict the fluid flow between the cooling fins at a first specified low temperature of the heat-generating device. A second shape memory material may expand at a second specified lower temperature of the heat-generating device to further restrict the fluid flow through the cooling fins. Conversely, the first and second shape memory materials will have differing temperatures of contraction at which they do not act to restrict the fluid flow through the cooling fins. Therefore, the amount of fluid flow restricted can be carefully and passively controlled.

The shape memory material can be disposed in contact with the cooling fins in various ways. The shape memory material may be coated upon the cooling fins, molded and inserted as a rigid structure, held in place by a clip, held in place by a slot or groove created upon the fin for this purpose, or any other method which will keep the material properly positioned in the fluid flow path and in thermal communication with the cooling fin.

In a third embodiment, a heat-generating device has cooling fins disposed in contact to dissipate heat. The shape memory polymers are disposed in a manner to restrict fluid flow through the cooling fins. The stimulus for the shape memory material to expand or contract is supplied from an external source. While commonly used stimuli are electrical, magnetic, or thermal, any stimulus activating the shape memory material can be applied. A preferred electrical stimulus is generated and sent to the shape memory material in response to the processor detecting that the temperature of the heat-generating device is out of the desired operating range or desired operating set point. The temperature sensor may be part of a chip set that includes the processor and the processor may be the heat-generating device itself. Other temperature control schemes using the shape memory materials can be readily envisioned.

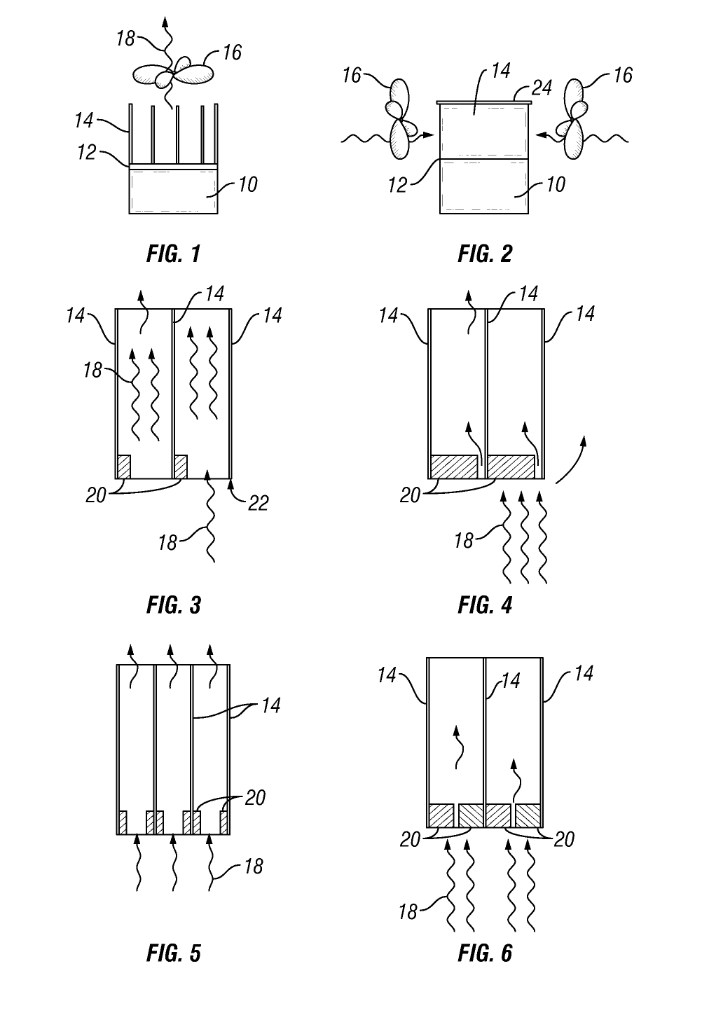

FIG. 1 is a side view of a typical heat-generating device 10 in thermal contact 12 with a heat sink having cooling fins 14. A fan 16 is sometimes utilized to force air through the cooling fins 14, or draw air through them. A common example of this arrangement is on the processor within a computer, where heat is removed through convection by air forced between the cooling fins. Another common example where fluid is utilized is the radiator used in automobiles, or to heat dwellings. In this example, a fan 16 is forcing the fluid flow 18 upward.

FIG. 2 is a side view of a typical heat-generating device 10 in thermal contact 12 with cooling fins 14. Also shown are two alternate placements for a single fan 16, or the utilization of multiple fans 16. The fan(s) 16 may be used to force air through the cooling fins 14, draw air through the cooling fins 14, or any combination of the above. While the cooling fins 14 are shown with an open top in FIG. 1, the invention is equally applicable to cooling fin assemblies that are closed, such as by securing a cover 24 over the top of the fins and passing cooling fluid through the paths defined between the cooling fins 14 and under the cover 24. The use of a cover 24 would also serve to increase the control of fluid flow between the fins.

FIG. 3 is a plan view of cooling fins 14 disposed upon a heat-generating device (not shown for clarity). The cooling fins 14 each have a shape memory material 20 disposed at an upstream end of the fin to restrict fluid flow 18 at the entry to the fins. This shape memory material disposition assumes unidirectional flow of fluid 18 across the fins, and effective fluid flow 18 restriction is accomplished at the entryway. The shape memory material 20, while spanning the entire leading edge 22 of the cooling fin 14, occupies as little surface area of the fin as possible in order to maintain the thermal exchange characteristics of the cooling fins 14 over those portions of the cooling fins 14 that are not covered by the material.

FIG. 4 is a plan view of cooling fins 14 disposed upon a heat-generating device (not shown for clarity). The cooling fins 14 each have a shape memory material 20 disposed at an upstream end of the fin to restrict fluid flow 18 at the entry to the fins. The shape memory material 20 is shown when expanded to restrict fluid flow 18 through the cooling fins 14.

FIG. 5 is a plan view of cooling fins 14 disposed upon a heat-generating device (not shown for clarity). The cooling fins 14 each have a shape memory material 20 disposed at an upstream end of the fin to restrict fluid flow 18 at the entry to the fins. This shape memory material disposition assumes unidirectional flow of fluid 18 across the fins, and effective fluid flow 18 restriction is accomplished at the entryway. The shape memory material 20 occupies as little surface area of the cooling fins 14 as possible, in order to maintain the thermal exchange characteristics of the cooling fins 14 over those portions of the cooling fins that are not covered by the shape memory material 20. In this embodiment, the shape memory material 20 is disposed on both sides of the cooling fins 14.

FIG. 6 is a plan view of cooling fins 14 having the shape memory material 20 of FIG. 5, where the shape memory material 20 is expanded to restrict fluid flow 18 through the cooling fins 14.

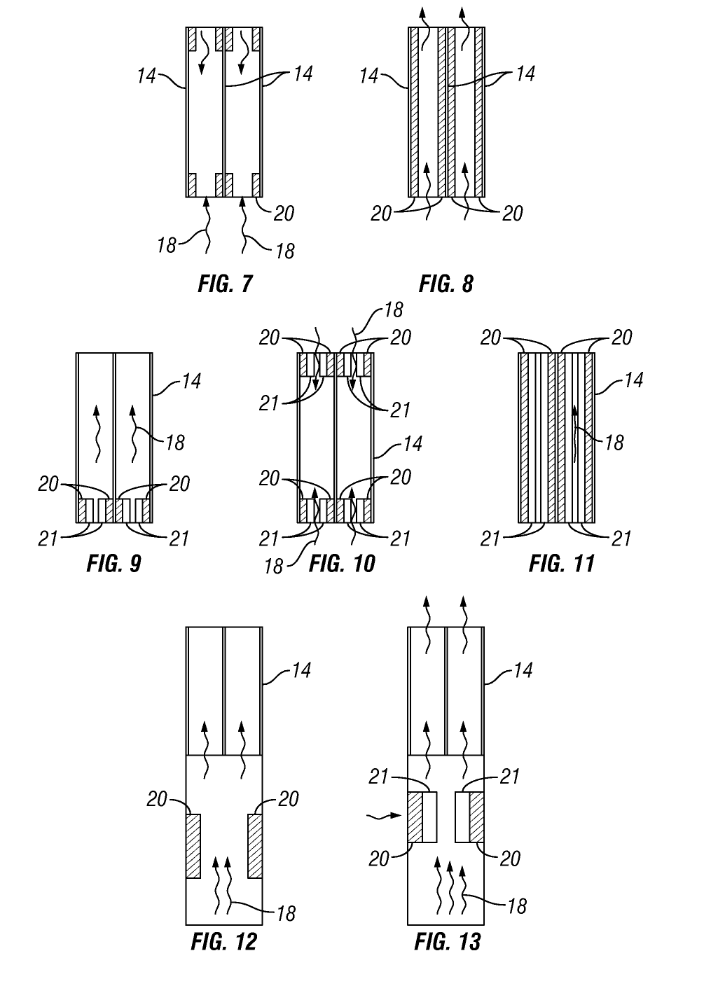

FIG. 7 is a plan view of cooling fins 14 disposed upon a heat-generating device (not shown for clarity). In this embodiment, the shape memory material 20 is disposed at both ends of the cooling fins 14 to restrict fluid flow 18 at either end to the cooling fins 14. This will be the effective disposition when fluid 18 enters at either end of the cooling fins 14, and is expelled elsewhere, such as through the top of the cooling fins 14. The shape memory material 20 occupies as little surface area as possible, in order to maintain the thermal exchange characteristics of the cooling fins 14.

FIG. 8 is a plan view of cooling fins 14 disposed upon a heat-generating device (not shown for clarity). In this further embodiment, the shape memory material 20 is disposed across the entire length of the cooling fin 14 to restrict fluid flow 18. This will be the preferred disposition when the shape memory material 20 has desirable thermal exchange characteristics, or will not affect the thermal exchange characteristics of the cooling fins 14.

FIG. 9 is a plan view of cooling fins 14 disposed upon a heat-generating device (not shown for clarity). A plurality of shape memory materials 20, 21 is disposed at one end of the cooling fins 14 to restrict fluid flow 18 at the entry to the cooling fins 14. A first shape memory material 20 is selected to expand and contract at a different temperature than a second shape memory material 21. By utilizing a plurality of shape memory materials, fluid flow 18 can be restricted totally, restricted partially, or not restricted. This embodiment assumes unidirectional fluid flow 18 across the cooling fins 14, and effective fluid flow 18 restriction is accomplished at the entryway. The shape memory materials 20, 21 occupy as little surface area as possible, in order to maintain the thermal exchange characteristics of the cooling fins 14.

FIG. 10 is a plan view of cooling fins 14 having a plurality of shape memory materials 20, 21 disposed at both ends of the cooling fins 14 to restrict fluid flow 18 at the entry to the cooling fins 14. This will be the effective disposition when fluid enters at either end of the cooling fins 14, and is expelled elsewhere, such as through the top of the cooling fins 14. The shape memory materials 20, 21 occupy as little surface area as possible, in order to maintain the thermal exchange characteristics of the cooling fins 14.

FIG. 11 is a plan view of cooling fins 14 disposed upon a heat-generating device (not shown for clarity). A plurality of shape memory materials 20, 21 is disposed across the entire cooling fin 14 to restrict fluid flow 18. This will be the preferred disposition when the shape memory materials 20, 21 have desirable thermal exchange characteristics, or will not affect the thermal exchange characteristics of the cooling fins 14.

FIG. 12 is a plan view of cooling fins 14 disposed upon a heat-generating device (not shown for clarity). In this alternative embodiment, the shape memory material 20 is disposed in the path of fluid flow 18 to the cooling fins 14, but is not necessarily in thermal contact with the cooling fins 14. In this embodiment, the shape memory material 20 expands or contracts in response to an external stimulus. The external stimulus may take the form of electrical current, heat, a magnetic field, light, or anything else that induces the shape memory material to expand or contract.

FIG. 13 is a plan view of cooling fins 14 disposed upon a heat-generating device (not shown for clarity). A plurality of shape memory materials 20, 21 is disposed in the path of fluid flow 18 to the cooling fins 14, but are not necessarily in thermal contact with the cooling fins 14. In this embodiment, the shape memory materials 20, 21 expand or contract in response to an external stimulus. The shape memory materials 20, 21 will preferably also have differing characteristics of expansion and contraction in response to the external stimulus. The external stimulus may take the form of electrical current, heat, a magnetic field, light, or anything else that induces the shape memory material to expand or contract. Alternatively, the shape memory materials 20, 21 may be the same material, but receive separate electrical stimuli for controllably producing different degrees of restriction.

The terms “comprising,” “including,” and “having,” as used in the claims and specification herein, shall be considered as indicating an open group that may include other elements not specified. The terms “a,” “an,” and the singular forms of words shall be taken to include the plural form of the same words, such that the terms mean that one or more of something is provided. The term “one” or “single” may be used to indicate that one and only one of something is intended. Similarly, other specific integer values, such as “two,” may be used when a specific number of things is intended. The terms “preferably,” “preferred,” “prefer,” “optionally,” “may,” and similar terms are used to indicate that an item, condition or step being referred to is an optional (not required) feature of the invention.

While the invention has been described with respect to a limited number of embodiments, those skilled in the art, having benefit of this disclosure, will appreciate that other embodiments can be devised which do not depart from the scope of the invention as disclosed herein. Accordingly, the scope of the invention should be limited only by the attached claims.

What is claimed is:

1. An apparatus to regulate the temperature of a heat-generating device within a specified range comprising:
a plurality of cooling fins disposed in thermal communication with the heat-generating device;
a means for flowing fluid along a path between cooling fins;
a shape memory material in the path of the fluid flow between said cooling fins; and
the shape memory material in communication with a stimulus causing the shape memory material to expand or contract.

2. The apparatus of claim 1, wherein the shape memory material acts to restrict fluid flow at temperatures less than a desired temperature of the heat-generating device, and does not act to restrict fluid flow at temperatures greater than a different desired temperature of the heat-generating device.

3. The apparatus of claim 1, wherein the stimulus is the temperature of the heat-generating device.

4. The apparatus of claim 1, wherein the shape memory material expands and contracts in response to an applied stimulus.

5. The apparatus of claim 1, wherein the fluid is selected from air, liquid, and combinations thereof.

6. The apparatus of claim 1, further comprising:
a plurality of shape memory materials in the path of the fluid flow between said cooling fins, wherein the shape memory materials expand and contract in response to different levels of stimuli.

7. The apparatus of claim 1, further comprising:
a plurality of shape memory materials in the path of the fluid flow between said cooling fins, wherein the shape memory materials expand and contract in response to different stimuli.

8. The apparatus of claim 1, further comprising:
a plurality of heat-generating devices;
a plurality of cooling fins disposed in thermal communication with each heat-generating device;
a means for flowing fluid along a path between cooling fins; and
a shape memory material in the path of the fluid flow between said cooling fins, wherein the shape memory material is selected for each heat-generating device to regulate the desired temperature range of the heat-generating device.

9. The apparatus of claim 8, wherein the shape memory material expands and contracts in response to the temperature of the heat-generating device.

10. The apparatus of claim 8, wherein the shape memory materials expand and contract in response to an applied stimulus.

11. The apparatus of claim 8, wherein the fluid is selected from air, liquid, and combinations thereof.

12. The apparatus of claim 8, further comprising:
a plurality of shape memory materials in the path of the fluid flow between said cooling fins, wherein each shape memory material expands and contracts in response to different levels of stimuli.

13. A method comprising:
conveying fluid through a passageway to cool a heat-generating device; and
regulating the amount of fluid conveyed through the passageway by utilizing a shape memory material disposed in the passageway, wherein the shape memory material expands and contracts in response to an applied stimulus.

14. The method of claim 13, wherein the shape memory material restricts fluid flow at temperatures less than a desired device temperature, and does not restrict fluid flow at temperatures greater than a different desired device temperature.

15. The apparatus of claim 13, wherein the shape memory material is in thermal communication with the heat-generating device, and wherein the shape memory material expands and contracts in response to the temperature of the heat-generating device.

16. The method of claim 13, wherein the applied stimulus is an electrical current.

17. The method of claim 13, wherein the temperature is regulated utilizing a plurality of shape memory materials with varying expansion and contraction characteristics.
